(19) United States
(12) Patent Application Publication
(10) Pub. No.: US 2008/0034580 A1
(43) Pub. Date: Feb. 14, 2008

(54) Suspension-terminal connecting apparatus and method of manufacturing suspension assembly

(75) Inventors: Tetsuo Saito, Kawasaki (JP); Keisuke Fukuda, Kawasaki (JP); Yukio Kato, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED

(21) Appl. No.: 11/637,561

(22) Filed: Dec. 12, 2006

(30) Foreign Application Priority Data
Aug. 14, 2006 (JP) 2006-221181

(51) Int. Cl. G11C 5/12

(52) U.S. Cl. 29/737; 29/747; 29/748

(57) ABSTRACT

A terminal pressing unit collectively presses terminals of a plurality of suspensions constituting a head suspension assembly including the suspensions and an actuator block against terminals of the actuator block. A terminal connecting unit connects the terminals of the suspensions with the terminals of the actuator block.

### BACKGROUND OF THE INVENTION

1. Field of the Invention

The present invention generally relates to a technology for connecting terminals of a plurality of suspensions constituting a suspension array with terminals of an actuator block.

2. Description of the Related Art

Conventionally, a head suspension assembly (HSA) is employed in a magnetic disk device to write (record) recorded data in a magnetic disk or to read (reproduce) the recorded data from the magnetic disk.

In recent years, following downsizing and improved precision of magnetic disk devices, operation for electrically connecting a terminal of each of suspensions to that of an actuator block during manufacturing of an HSA that includes the suspensions and the actuator block has increasingly become so important as to influence product yield and product reliability.

To connect the terminal of the suspension to the terminal of the actuator block, the following two methods are conventionally adopted. First, the terminal of the suspension is bridge-connected to the terminal of the actuator block by soldering while making them apart from each other to some extent. Second, a terminal of a flexible printed circuit board is connected to a terminal of a wire trace of an HSA by soldering or ultrasonic bonding while making them contact with each other or making them sufficiently close to each other. If the first method is adopted, it is necessary to use a device for satisfactorily melting and solidifying solder into bridge shape to mass-produce HSAs. If the second method is adopted, the HSAs can be mass-produced despite manual work. If the terminals of the suspensions are to be connected to the respective terminals of the actuator block, the terminals of suspensions cannot be aligned due to irregularity in thickness of suspensions when the terminals of the suspensions are built up on the terminals of the actuator block. As a result, an operator disadvantageously needs to perform positioning operation or the like with respect to the terminals of the suspensions.

FIG. 8 is a schematic of entire configurations of the conventional HSA and the conventional terminal connecting apparatus. FIG. 9 is an enlarged side view of the conventional HSA and the conventional terminal connecting apparatus, viewed from an A direction shown in FIG. 8.

As shown in FIGS. 8 and 9, an HSA 10 includes an actuator unit 23 that includes a plurality of suspensions 20 (eight in the example shown in FIG. 8) and a plurality of actuator arms 22, and an actuator block 30. A magnetic head 21 is provided on a tip end of each suspension 20. A plurality of terminals 26 (eight in the example shown in FIG. 8) are provided on rear ends (lower side in FIG. 8) of the actuator arms 22.

The actuator block 30 includes a pivot housing 32 that includes a pivot bearing 31 and a coil support 42 that holds a voice coil 41 fixed to a rear end (lower side in FIG. 8) of the pivot housing 32. A plurality of terminals 34 (eight in the example shown in FIG. 8) is provided to be aligned on an upper surface of the pivot housing 32 (see FIG. 4).

A conventional terminal connecting apparatus 50a includes a pressure actuator 80a and a terminal connection chip 90. The pressure actuator 80a presses the terminals 26 of the suspensions 20 against the terminals 34 (see FIG. 4) of the actuator block 30, respectively. The terminal connection chip 90 superimposes the terminals 26 on the terminals 34 and connects the terminals 26 to the terminals 34, respectively.

In the HSA 10 shown in FIGS. 8 and 9, if the terminals 26 of the suspensions 20 are to be connected to the terminals 34 of the actuator block 30, then the terminals 26 are positioned relative to the respective terminals 34, and the pressure actuator 80a presses the terminals 26 from above. Furthermore, the terminals 26 are connected to the terminals 34 by soldering or the like using the terminal connection chip 90.

Referring to a flowchart of FIG. 10, procedures of connecting the terminals 26 of the suspensions 20 to the respective terminals 34 of the actuator block 30 will be explained in detail.

The HSA 10 is inserted (step S110), and a suspension-position measuring processing for measuring a present position of each suspension 20 is performed (step S120). The suspension-position measuring processing is intended to position the terminal 26 of each suspension 20 relative to each terminal 34 of the actuator block 30.

A suspension-position correction processing for correcting the position of the suspension 20 to a normal position is performed based on the measured position (step S130). A suspension-terminal connection processing for connecting the terminal 26 of each suspension 20 to each terminal 34 of the actuator block 30 is performed based on the position of the suspension 20 corrected at the step S130 (step S140).

The processing from the steps S120 to the step S140 is repeatedly performed by as much as the number of suspensions 20 that constitute the HSA 10. If connection of the terminals 26 of all the suspensions 20 to the respective terminals 34 of the actuator block 30 is completed (Yes at step S150), the HSA 10 is ejected (step S160).

As explained with reference to the flowchart of FIG. 10, with the conventional connecting method for the terminals 26 of the suspensions 20, the terminal 26 of each suspension 20 is connected to each terminal 34 of the actuator block 30 while the position of the terminal 26 is measured and corrected as needed. In this case, the connection operation is performed by either operator's manual-operation or image recognition of connected portions between the terminals 26 and 34 and actuator's automatic operation.

As a conventional technique related to the connection between the terminal of the suspension to the terminal of the actuator block of this type, Japanese Patent Application Laid-Open No. 2006-49751 discloses a technique for providing a backing member on an insulating layer of the terminal of each suspension.

According to the technique disclosed in Japanese Patent Application Laid-Open No. 2006-49751, even if a crack occurs while a solder is to be bonded to the terminal, the backing member of the terminal is bonded to the insulating layer. Therefore, conductivity is ensured. Moreover, the terminal of a flexible printed circuit board can be soldered to the terminal of the wire trace of the suspension assembly without causing a soldering failure or the like.

However, the conventional method of connecting the terminal of the suspension to that of the actuator block has the following problems. The positioning of the terminal of the suspension relative to that of the actuator block is performed either by operator's manual operation or the image recognition and actuator's automatic operation. Specifically, the terminal 26 of the suspension 20 is connected to the terminal 34 of the actuator block while the operator makes position measurement and position correction at needed. Due to this, the connection step cannot be started until the positioning of the terminals is performed. This disadvantageously increases operation time, reduces the number of produced HSAs, and thereby causes cost hike.

### SUMMARY OF THE INVENTION

It is an object of the present invention to at least partially solve the problems in the conventional technology.

An apparatus according to one aspect of the present invention is for connecting terminals of a plurality of suspensions constituting a head suspension assembly including the suspensions and an actuator block with terminals of the actuator block. The apparatus includes a terminal pressing unit that collectively presses the terminals of the suspensions against the terminals of the actuator block; and a terminal connecting unit that connects the terminals of the suspensions with the terminals of the actuator block.

An apparatus according to another aspect of the present invention is for connecting terminals of a plurality of suspensions constituting a head suspension assembly including the suspensions and an actuator block with terminals of the actuator block. The apparatus includes a terminal pressing unit that collectively presses the terminals of the suspensions against the terminals of the actuator block; a terminal connecting unit that connects the terminals of the suspensions with the terminals of the actuator block; and a lateral positioning unit for positioning the terminals of the suspensions and the terminals of the actuator block in a lateral direction when connecting the terminals of the suspensions with the terminals of the actuator block.

A method according to still another aspect of the present invention is for manufacturing a suspension assembly including at least a plurality of suspensions and an actuator block. The method includes positioning each of the suspensions in a longitudinal direction when connecting terminals of the suspensions with terminals of the actuator block; positioning the terminals of the suspensions and the terminals of the actuator block in a lateral direction; pressing collectively the terminals of the suspensions against the terminals of the actuator block; and connecting the terminals of the suspensions with the terminals of the actuator block.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic of entire configurations of an HSA and a terminal connecting apparatus according to an embodiment of the present invention;

FIG. 2 is an enlarged side view of the HSA and the terminal connecting apparatus, viewed from a direction A shown in FIG. 1;

FIG. 3 is an enlarged view of a part B shown in FIG. 1;

FIG. 4 is an enlarged view of a part C shown in FIG. 1;

FIG. 5A is an enlarged view of a modified configuration of a pressure actuator;

FIG. 5B an enlarged view of another modified configuration of a pressure actuator;

FIG. 6 is schematic for explaining longitudinal positioning;

FIG. 7 is a flowchart of procedures of connection processing for terminals of suspensions;

FIG. 8 is a schematic of entire configurations of a conventional HSA and a conventional terminal connecting apparatus;

FIG. 9 is an enlarged side view of the conventional HSA and the conventional terminal connecting apparatus, viewed from a direction A shown in FIG. 8; and

FIG. 10 is a flowchart of procedures of connection processing for terminals of suspensions according to a conventional technique.

### DETAILED DESCRIPTION OF THE PREFERRED EMBODIMENTS

Exemplary embodiments of the present invention will be explained in detail below with reference to the accompanying drawings. It is to be noted that the present invention is not limited to the embodiments.

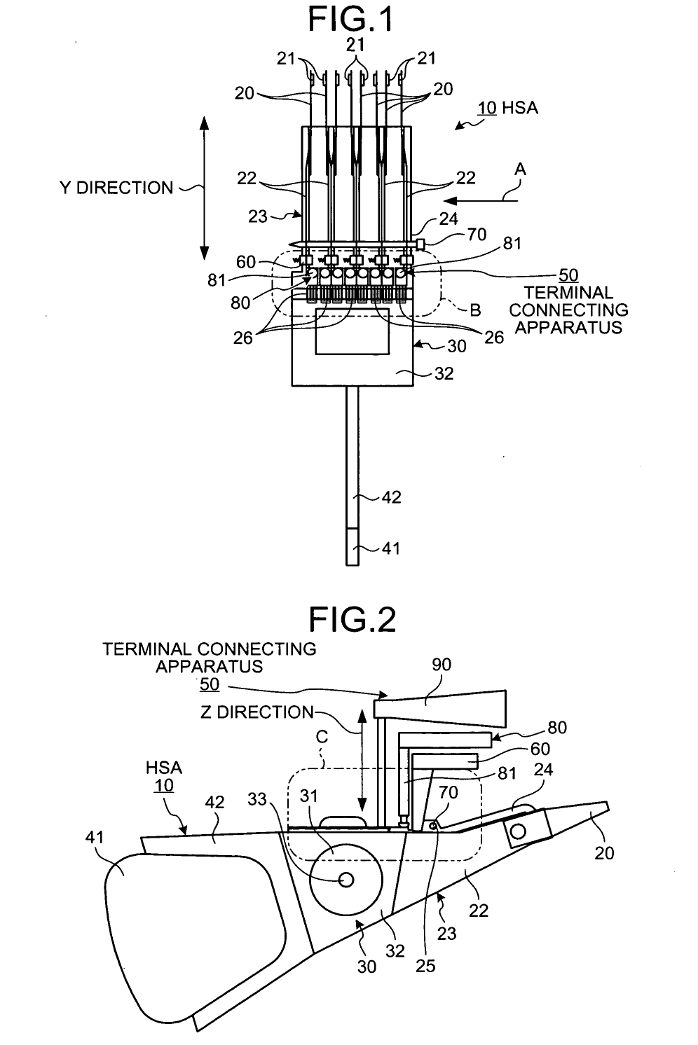

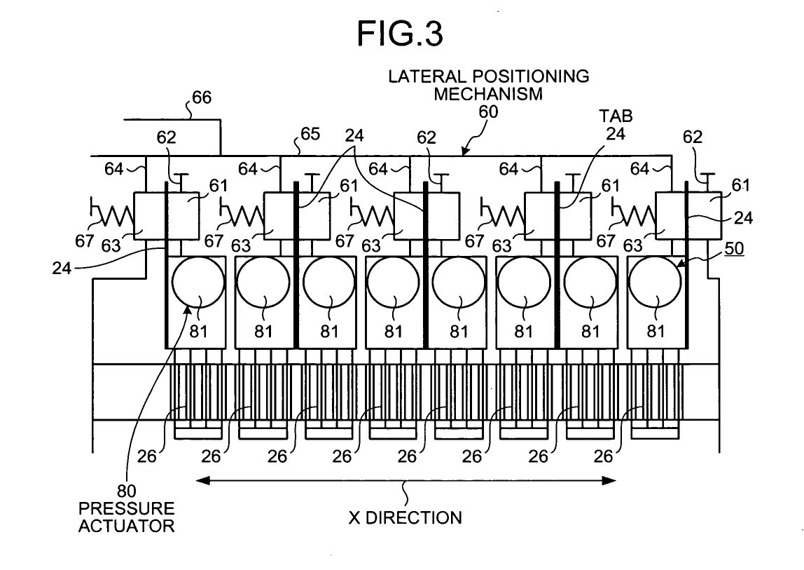

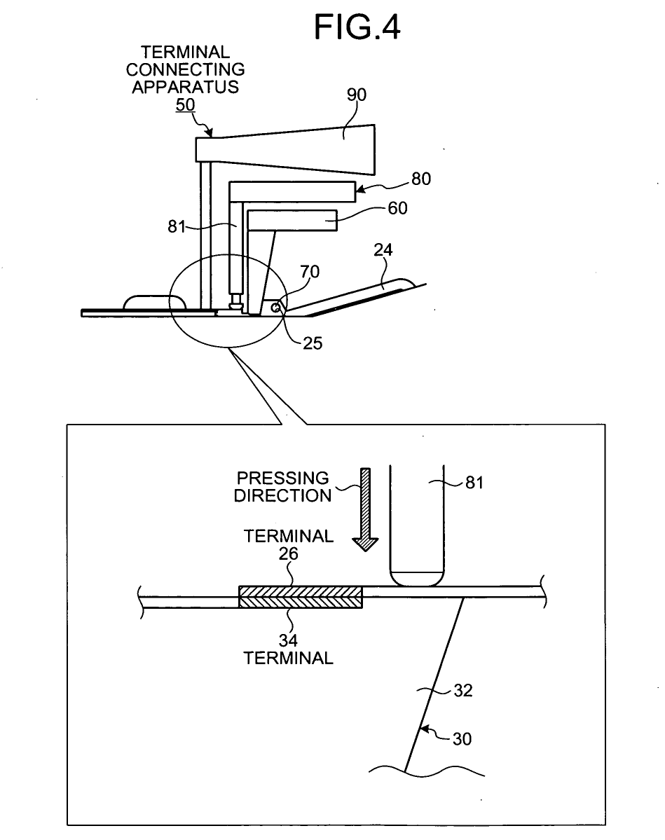

FIG. 1 is a schematic of entire configurations of the HSA 10 and a terminal connecting apparatus 50 according to the embodiment of the present invention. FIG. 2 is an enlarged side view of the HSA 10 and the terminal connecting apparatus 50, viewed from the A direction shown in FIG. 1. FIG. 3 is an enlarged view of a part B shown in FIG. 1, and FIG. 4 is an enlarged view of a part C shown in FIG. 1.

As shown in FIGS. 1 and 2, the HSA 10 includes the actuator unit 23 that includes a plurality of suspensions 20 (eight in the example shown in FIG. 1) and a plurality of actuator arms 22 (five in the example shown in FIG. 1), and the actuator block 30.

The suspensions 20 are provided to be aligned in a comb-like fashion, and magnetic heads 21 each for recording/reproducing data in/from a disk are provided on tip ends of the respective suspensions 20. The actuator arms 22 are coupled to rear ends of the suspensions 20. Moreover, rear ends of the actuator arms 22 are fixedly coupled to the actuator block 30.

The suspension 20 can be manufactured by drawing, for example, a stainless plate or aluminum and then machining the drawn stainless plate or aluminum into a predetermined shape. Furthermore, a plurality of terminals 26 (eight in the example shown in FIG. 1) are provided on the rear ends (lower side in FIG. 1) of the actuator arms 22.

The actuator block 30 includes the pivot housing 32 that includes the pivot bearing 31 and the coil support 42 that holds the voice coil 41 fixed to the rear end (lower side in FIG. 1) of the pivot housing 32. A plurality of terminals 34 (eight in the example shown in FIG. 1) is provided to be aligned on the upper surface of the pivot housing 32 (see FIG. 4).

The terminal connecting apparatus 50 connects the terminal 26 provided on the actuator arm 22 of the suspension 20 to the terminal 34 provided on the pivot housing 32 as will be explained later in detail.

A voice coil yoke (not shown) that constitutes, together with the voice coil 41, a voice coil motor is arranged on a rear end (lower side in FIG. 1) of the pivot housing 32. A permanent magnet is attached inside the voice coil yoke to generate an electromagnetic field. The suspensions 20 can thereby rotate around a pivot shaft 33 of the pivot bearing 31 provided in the pivot housing 32.

A tab 24 (see FIG. 2) protruding upward is provided on an upper surface of each suspension 20, and a circular hole 25 is formed at a predetermined position on the tab 24. The terminal connecting apparatus 50 can position the suspensions 20 in a lateral direction by moving the suspensions 20 in the lateral direction (X direction in FIG. 4) while holding the tab 24 of each suspension 20. Moreover, by inserting a longitudinal positioning pin 70 into the circular hole 25 formed in the tab 24 of each suspension 20, the terminal connecting apparatus 50 can position the suspensions in the longitudinal direction.

In case of the HSA 10 shown in FIGS. 1 and 2, the magnetic heads 21 (eight in the example shown in FIG. 1) provided on the respective suspensions 20 can reproduce/record data from/on front and rear sides of four disks.

As explained, the HSA 10 is configured so that the actuator arms 22 coupled to the suspensions 20, the actuator block 30, and the coil support 42 including the voice coil 41 are fixedly assembled with one another. As shown in FIG. 4, during assembly of the suspensions 20 with the actuator block 30, the terminal connecting apparatus 50 can connect the terminals 26 provided on the rear ends of the actuator arms 22 to the terminals 34 provided on the upper surface (upper side in FIG. 4) of the pivot housing 32, respectively.

The terminal connecting apparatus 50 according to the embodiment is characterized as follows. To connect the terminals 26 of the suspensions 20 to the respective terminals 34 of the actuator block 30, the terminals 26 of all the suspensions 20 are integrally connected to and integrally positioned relative to the respective terminals 34 of the actuator block 30 differently from the conventional technique. According to the conventional terminal connecting apparatus 50a, the connection and positioning are performed per suspension. Furthermore, during the connection of the terminals 26 to the respective terminals 34, it is possible to accurately and easily perform lateral (X-direction) positioning (1), longitudinal (Y-direction) positioning (2), and height-direction (Z-direction) positioning (3).

The lateral (X-direction) positioning (1) is performed to correct a lateral displacement generated when the terminal 26 is connected to each terminal 34. The longitudinal (Y-direction) positioning (2) is performed to align the terminals 26 of the suspensions 20 in the longitudinal direction using the longitudinal positioning pin 70 (see FIG. 1). The height-direction (Z-direction) positioning (3) is performed to position a height position of the terminal 26 relative to the terminal 34 during the connection between the terminals 26 and 34 using a pressure pin 81 of each pressure actuator 80 (see FIGS. 2 and 4).

To perform these positioning operations, the terminal connecting apparatus 50 includes the pressure actuator 80, the terminal connection chip 90, and a lateral positioning mechanism 60 as shown in FIGS. 1 to 3. The pressure actuator 80 includes a plurality of pressure pins 81 (eight in the example shown in FIG. 3) for pressing the terminals 26 of the suspensions 20 against the respective terminals 34 of the actuator block 30 and for positioning heights of the terminals 26 of the suspensions 20. The terminal connection chip 90 connects the terminals 26 to the terminals 34 by soldering or the like. The lateral positioning mechanism 60 positions the terminals 26 and 34 relative to each other in the lateral direction (X direction).

As shown in FIG. 3, the lateral positioning mechanism 60 includes fixed claws 61, fixed support members 62 fixing the respective fixed claws 61, moving claws 63, fixed support members 64 fixing the respective moving claws 63, compression spring members 67 applying predetermined elastic forces to the respective moving claws 63, a moving support member 65 that integrally moves the fixed support members 64, and a moving arm member 66. In ordinary state, the moving claws 63 are pressed against the fixed claws 61 by the elastic forces of the compression spring members 67, respectively.

Namely, the moving claw 63 is configured to hold the tab 24 of each suspension 20 between the moving claw 63 and the fixed claw 61 and to integrally and freely move the suspensions 20 in the lateral direction (X direction).

It is thereby possible to integrally position the terminals 26 of the suspensions 20 in the lateral direction. In the embodiment, a compression spring is used as the compression spring member. Alternatively, a plate spring or the like can be used as the compression spring member.

As shown in FIG. 3, the pressure actuator 80 includes a plurality of pressure pins 81 (eight in the example shown in FIG. 3). The pressure actuator 80 functions to press the terminals 26 from above against the terminals 34 using the respective pressure pins 81 while performing the lateral (X-direction) positioning (1), the longitudinal (Y-direction) positioning (2), and the height-direction (Z-direction) positioning (3).

The pressure pins 81 are arranged at positions corresponding to positions of the terminals 26 of the suspensions 20 and the terminals 34 of the actuator block (at equal intervals). It is thereby possible to apply almost equal pressure to the terminals 26.

As a result, the terminal connecting apparatus 50 can integrally press the terminals 26 and 34, and ensure preventing positional deviations of the connection between the terminals 26 and 34 generated when the pressure actuator 80 contacts with the terminals 26.

Moreover, as shown in FIG. 3, the terminal connection chip 90 functions to connect the terminals 26 of the suspensions 20 to the terminals 34 of the actuator block 30 by soldering after the terminals 26 and 34 are positioned in the lateral direction (X direction) (1), the longitudinal direction (Y direction) (2), and the height direction (Z direction) (3).

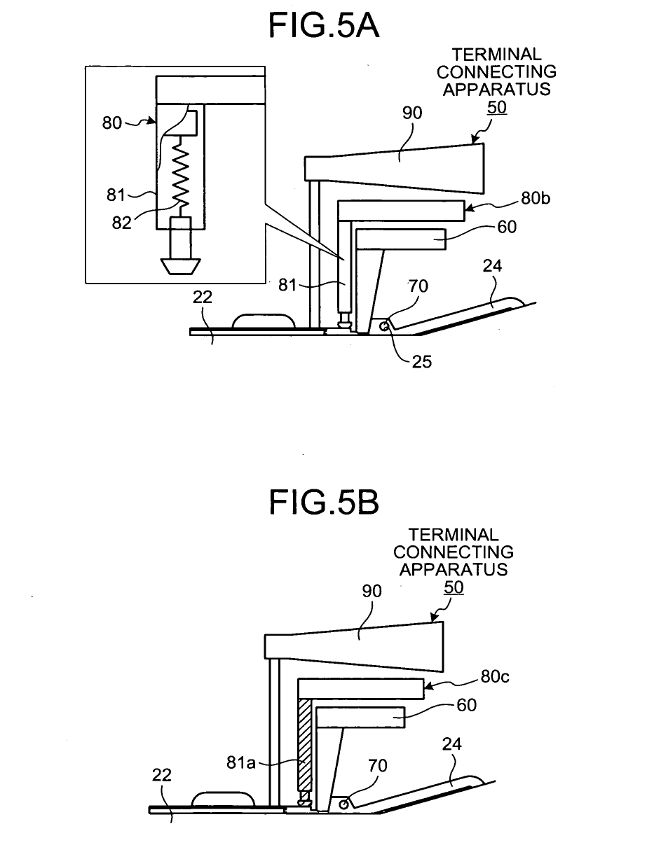

Referring to FIGS. 5A and 5B, modified configurations of the pressure actuator 80 will be explained. In a modification shown in FIG. 5A, a pressure actuator 80b is configured so that a compression spring 82 is provided in the pressure pin 81. The pressure actuator 80b shown in FIG. 5A can absorb and correct a positional deviation of the connection between the terminals 26 and 34 resulting from the thickness of the suspension 20 or the like by an elastic force of the compression spring 82 during pressing of the terminal 26 by the pressure pin 81. It is thereby possible to improve accuracy of the positioning of the terminal 26 relative to the terminal 34.

In a modification shown in FIG. 5B, a pressure actuator 80c is configured so that a pressure pin 81a is an elastic member. Similarly to the pressure actuator 80b, the pressure actuator 80c shown in FIG. 5B can absorb and correct a positional deviation of the connection between the terminals 26 and 34 resulting from the thickness of the suspension 20 or the like by an elastic force of the pressure pin 81 made of the elastic material during pressing of the terminal 26 by the pressure pin 81. It is thereby possible to improve accuracy of the positioning of the terminal 26 relative to the terminal 34.

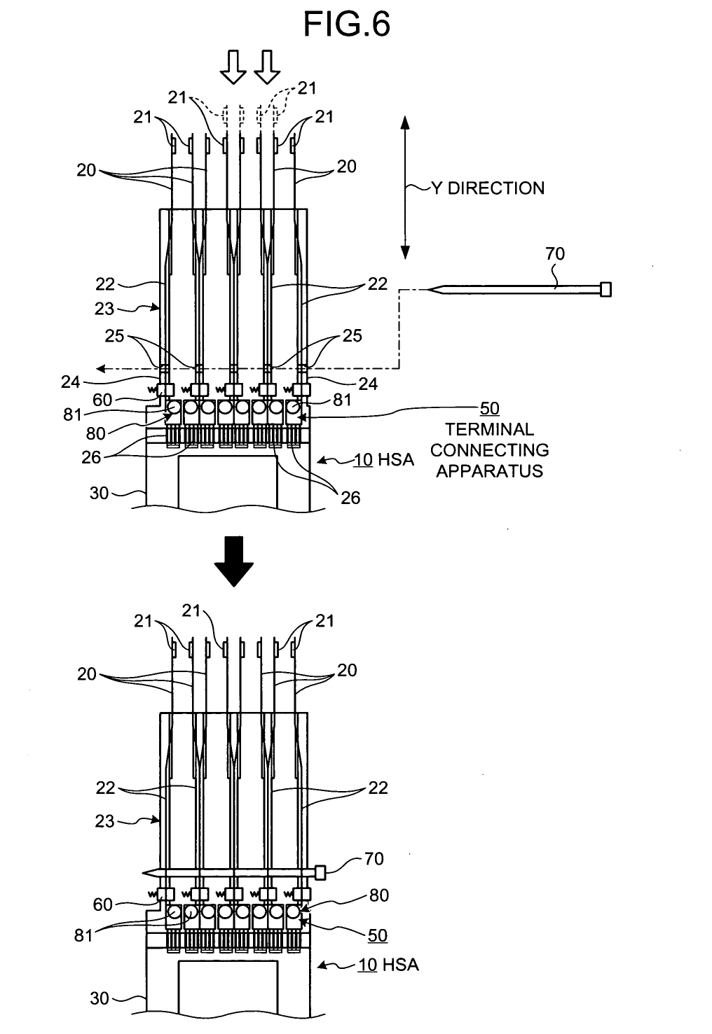

Referring to FIG. 6, the longitudinal (Z-direction) positioning with respect to the suspensions 20 that constitute the HSA 10 will be explained.

As shown in FIG. 6, even if longitudinal positional deviations occur to part of the suspensions 20 (indicated by dotted lines) among all the suspensions 20 that constitute the HSA 10, all the suspensions 20 can be integrally positioned in the longitudinal direction by inserting the longitudinal positioning pin 70 into the circular hole 25 formed in the tab 24 of each suspension 20.

It is thereby possible to easily and accurately position the terminals 26 of the suspensions 20 relative to the terminals 34 of the actuator block 30 in the longitudinal direction. Furthermore, if the terminals 26 of the suspensions 20 are connected to the respective terminals 34 of the actuator block 30, it is possible to ensure preventing longitudinal displacements in the connection between the terminals 26 to the terminals 34.

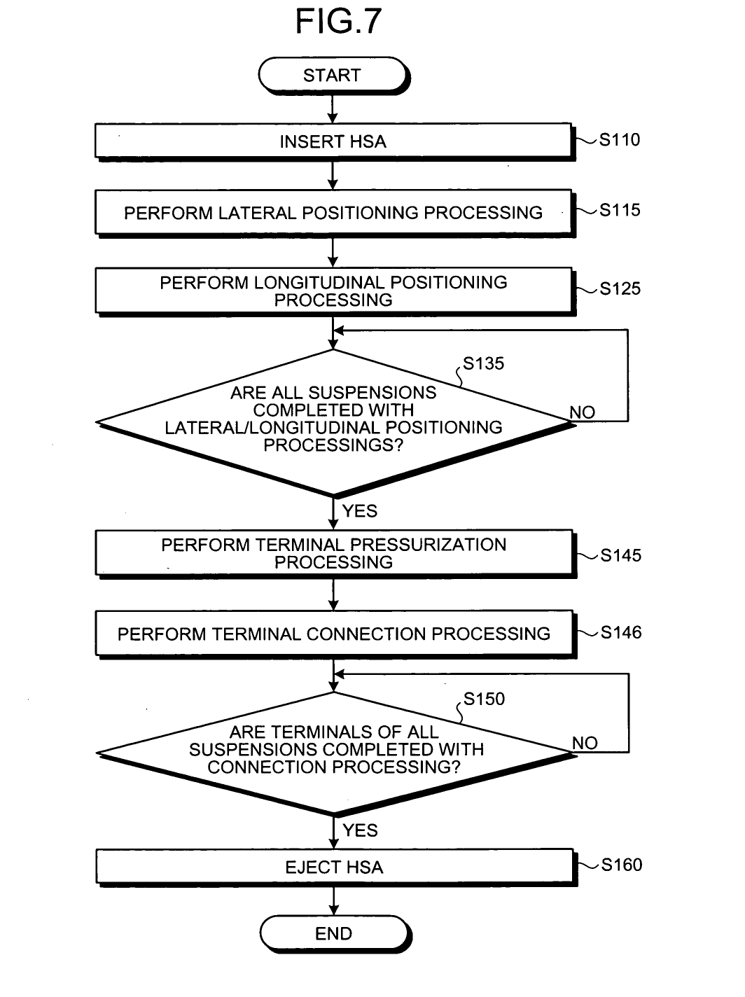

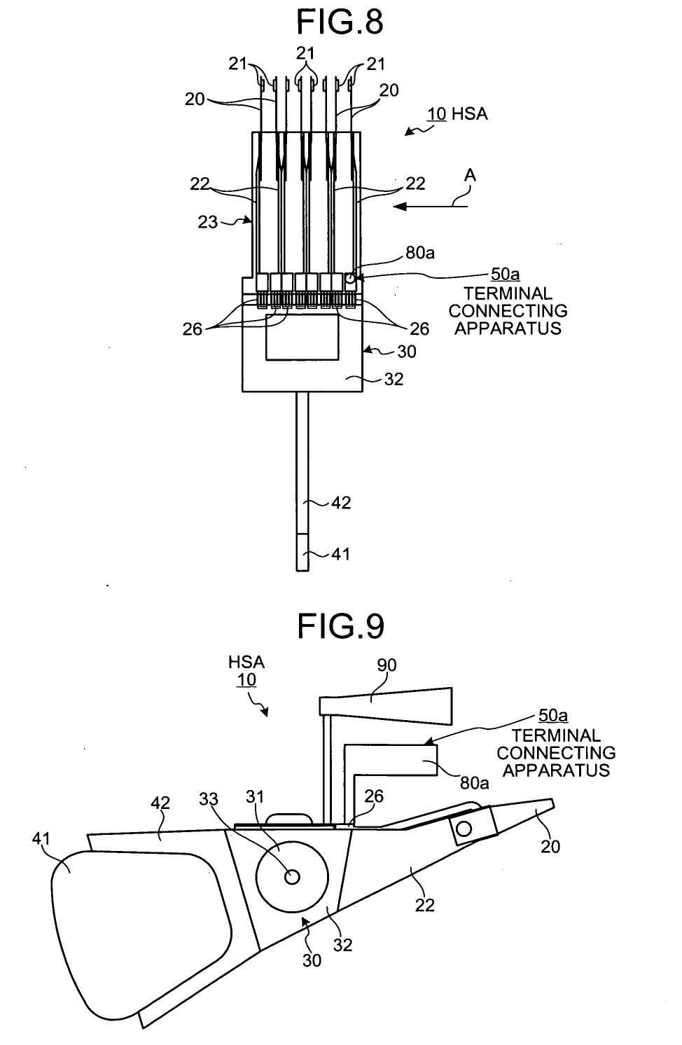

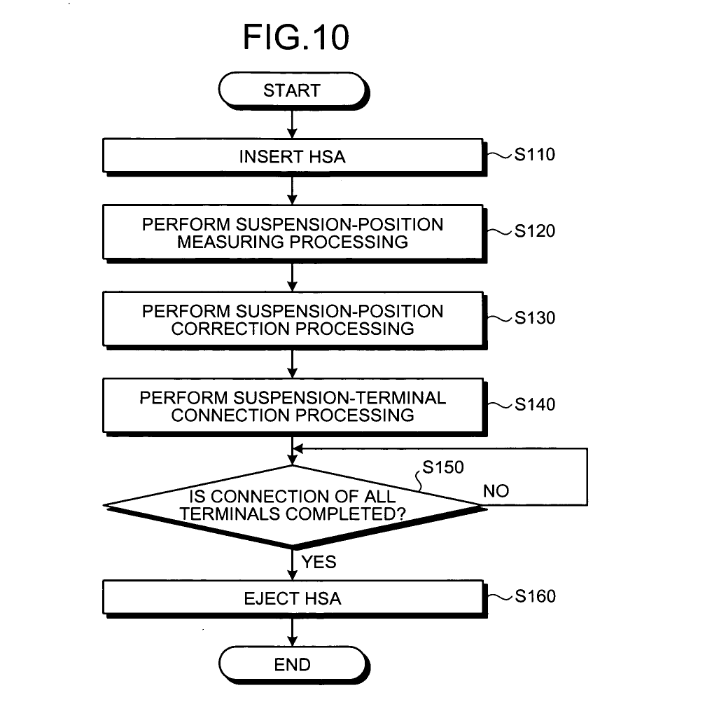

Referring to a flowchart of FIG. 7, procedures of the connection processing for connecting the terminals 26 of the suspensions 20 to the terminals 34 of the actuator block 30 will be explained.

As shown in FIG. 7, the HSA 10 is inserted (step S110). The lateral positioning mechanism 60 positions the terminal 26 of each suspension 20 in the lateral direction (step S115). The longitudinal positioning pin 70 positions the terminal 26 of each suspension 20 in the longitudinal direction (step S125). Specifically, the longitudinal positioning pin 70 is inserted into the circular hole 25 of the tab 24 of each suspension 20 to make an adjustment to set longitudinal positions of all the suspensions 20 equal.

It is determined whether all the suspensions 20 are completed with the lateral positioning processing and the longitudinal positioning processing at the steps S115 and S125, respectively (step S135). If all the suspensions 20 are completed with the lateral positioning processing and the longitudinal positioning processing (Yes at step S135), the processing goes to step S145. At the step S145, the pressure actuator 80 performs a terminal pressing process for pressing the terminals 26 of all the suspensions 20 against the respective terminals 34 of the actuator block 30 (step S145).

The terminal pressing process performed by the pressure actuator 80 enables simultaneously and sequentially connecting the terminals 26 of the suspensions 20 to the respective terminals 34 of the actuator block 30 by one operation. Furthermore, the terminals 26 can be held at predetermines positions (corresponding to the positions at which the respective terminals 34 of the actuator block 30 are arranged).

The terminal connection chip 90 performs a connection processing for connecting the terminals 26 to the terminals 34 by soldering (step S146). If it is determined that the terminals 26 of all the suspensions 20 are completed with the connection processing (Yes at step S150), the HSA 10 is ejected (step S160).

As explained so far, the terminal connecting apparatus 50 according to the embodiment includes the pressure actuator 80, the terminal connection chip 90, and the lateral positioning mechanism 60. The pressure actuator 80 integrally (simultaneously) pressures the terminals 26 of the suspensions 20 against the respective terminals 34 of the actuator block 30. The terminal connection chip 90 connects the terminals 26 of the suspension 20 to the respective terminals 34 of the actuator block 30. The lateral positioning mechanism 60 positions the terminals 26 relative to the terminals 34 in the lateral direction. Therefore, during the manufacturing of the HSA 10, the connection operation for connecting the terminals 26 of the suspensions 20 to the terminals 34 of the actuator block can be accurately and efficiently performed.

According to an experiment conducted by the inventor of the present invention, by performing the lateral, longitudinal, and height-direction positioning processes according to the embodiment, time required to position the suspensions 20 can be reduced to about 50% as compared with the conventional connection operation for connecting the terminal of each suspension to the terminal of the actuator block.

Namely, the result of the experiment indicates that it is possible to improve the number of produced HSAs, reduce cost, improve product reliability, and reduce production yield according to the embodiment.

In the embodiment, the suspension 20 includes the tab 24 in which the circular hole 25 into which the longitudinal positioning pin 70 is inserted. However, the circular hole 25 for the longitudinal positioning pin 70 is not always formed in the tab 24 of the suspension 20. The circular hole 25 can be replaced by an independently-provided suction nozzle.

As describe above, according to an embodiment of the present invention, the terminals of the suspensions can be simultaneously connected to the respective terminals of the actuator block by one operation in a sequential manner. It is thereby possible to reduce the operation time required for the terminal connection. Accordingly, the operation for connecting the terminals of the suspensions to the respective terminals of the actuator block can be accurately and efficiently performed. It is thereby possible to contribute to improvement of the number of produced HSAs and cost reduction.

Furthermore, according to an embodiment of the present invention, it is possible to integrally and accurately position the terminals of the suspensions in the height direction and the lateral direction.

Moreover, according to an embodiment of the present invention, during the connection of the terminals of the suspensions to the respective terminals of the actuator block, it is possible to ensure preventing the connection deviations among the terminals generated when the terminal pressing unit contacts with the terminals (positional deviations during pressing by the terminal pressing unit).

Furthermore, according to an embodiment of the present invention, during the connection of the terminals of the suspensions to the respective terminals of the actuator block, it is possible to easily and accurately position the terminals of the suspensions in the longitudinal direction.

Moreover, according to an embodiment of the present invention, the connection of the terminals of the suspensions to the respective terminals of the actuator block can be performed simultaneously and sequentially by one operation. It is thereby possible to reduce the operation time for the terminal connection processing. Accordingly, it is possible to accurately and efficiently perform the operation for connecting the terminals of the suspensions to the respective terminals of the actuator block. It is, therefore, possible to contribute to improvement of the number of produced HSAs and cost reduction.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. An apparatus for connecting terminals of a plurality of suspensions constituting a head suspension assembly including the suspensions and an actuator block with terminals of the actuator block, the apparatus comprising:
a terminal pressing unit that collectively presses the terminals of the suspensions against the terminals of the actuator block; and
a terminal connecting unit that connects the terminals of the suspensions with the terminals of the actuator block.

2. The apparatus according to claim 1, wherein
the terminal pressing unit includes same number of pressing units as the terminals of the suspensions, and
the pressing units are arranged at positions corresponding to array positions of the terminals of the suspensions.

3. The apparatus according to claim 2, wherein
the pressing units are arranged at positions corresponding to array positions of the terminals of the actuator block.

4. The apparatus according to claim 2, wherein
each of the pressing units includes a spring mechanism that applies a predetermined elastic force to each of the terminals of the suspensions when pressing the terminals of the suspensions.

5. The apparatus according to claim 2, wherein
each of the pressing units is formed with an elastic member that applies a predetermined elastic force to each of the terminals of the suspensions when pressing the terminals of the suspensions.

6. The apparatus according to claim 1, wherein
a hole is formed in a predetermined portion of each of the suspensions, and
a longitudinal alignment pin for positioning each of the suspensions in a longitudinal direction is inserted when connecting the terminals of the suspensions with the terminals of the actuator block.

7. An apparatus for connecting terminals of a plurality of suspensions constituting a head suspension assembly including the suspensions and an actuator block with terminals of the actuator block, the apparatus comprising:
a terminal pressing unit that collectively presses the terminals of the suspensions against the terminals of the actuator block;
a terminal connecting unit that connects the terminals of the suspensions with the terminals of the actuator block; and
a lateral positioning unit for positioning the terminals of the suspensions and the terminals of the actuator block in a lateral direction when connecting the terminals of the suspensions with the terminals of the actuator block.

8. The apparatus according to claim 7, wherein
the terminal pressing unit includes same number of pressing units as the terminals of the suspensions, and
the pressing units are arranged at positions corresponding to array positions of the terminals of the suspensions.

9. The apparatus according to claim 8, wherein
the pressing units are arranged at positions corresponding to array positions of the terminals of the actuator block.

10. The apparatus according to claim 8, wherein
each of the pressing units includes a spring mechanism that applies a predetermined elastic force to each of the terminals of the suspensions when pressing the terminals of the suspensions.

11. The apparatus according to claim 8, wherein
each of the pressing units is formed with an elastic member that applies a predetermined elastic force to each of the terminals of the suspensions when pressing the terminals of the suspensions.

12. The apparatus according to claim 7, wherein
a hole is formed in a predetermined portion of each of the suspensions, and
a longitudinal alignment pin for positioning each of the suspensions in a longitudinal direction is inserted when connecting the terminals of the suspensions with the terminals of the actuator block.

13. A method of manufacturing a suspension assembly including at least a plurality of suspensions and an actuator block, the method comprising:
positioning each of the suspensions in a longitudinal direction when connecting terminals of the suspensions with terminals of the actuator block;
positioning the terminals of the suspensions and the terminals of the actuator block in a lateral direction;
pressing collectively the terminals of the suspensions against the terminals of the actuator block; and
connecting the terminals of the suspensions with the terminals of the actuator block.
